(19) United States
(12) Patent Application Publication
(10) Pub. No.: US 2025/0176295 A1
(43) Pub. Date: May 29, 2025

(54) PHOTODETECTION DEVICE AND ELECTRONIC APPARATUS

(71) Applicant: SONY SEMICONDUCTOR SOLUTIONS CORPORATION, KANAGAWA (JP)

(72) Inventors: TOMOMI ITO, KANAGAWA (JP); ATSUSHI MASAGAKI, KANAGAWA (JP)

(21) Appl. No.: 18/837,512

(22) PCT Filed: Dec. 27, 2022
(86) PCT No.: PCT/JP2022/048389

§ 371 Date: Aug. 9, 2024

(30) Foreign Application Priority Data
Feb. 18, 2022 (JP) 2022-023641

(51) Int. Cl. H10F 39/00; H10F 39/18

(52) U.S. Cl. CPC H10F 39/807; H10F 39/014; H10F 39/182; H10F 39/80373; H10F 39/8067

(57) ABSTRACT

Provided is a photodetection device capable of obtaining an image with higher image quality. A configuration including a substrate, a plurality of photoelectric conversion units which is arranged two-dimensionally in the substrate, and a pixel separation portion which is arranged between the adjacent photoelectric conversion units and has a trench portion is adopted. Furthermore, a configuration is adopted in which in the substrate, a semiconductor region of an opposite conductivity type opposite to that of a charge accumulation region of the photoelectric conversion unit is formed in at least a part between the photoelectric conversion unit and the pixel separation portion. Then, the width of the trench portion is different for each of a plurality of regions obtained by dividing the substrate along the thickness direction. In a region where the semiconductor region of the opposite conductivity type is formed, the region being one of the plurality of regions, the width of the trench portion is greater in a region (first region) on a side of a surface of the substrate opposite to a light receiving surface of the substrate than in a region (second region) on a side closer to the light receiving surface of the substrate than the first region is. Moreover, the concentration of an impurity of the opposite conductivity type included in a part located at the interface with the pixel separation portion in the semiconductor region of the opposite conductivity type is made lower in the first region than in the second region.

### TECHNICAL FIELD

The present disclosure relates to a photodetection device and an electronic apparatus.

### BACKGROUND ART

Conventionally, there has been proposed a photodetection device including a substrate, a plurality of photoelectric conversion units two-dimensionally arranged in the substrate, and an inter-pixel light shielding wall arranged between the photoelectric conversion units, in which a p-type solid-phase diffusion layer is formed between the inter-pixel light shielding wall and the photoelectric conversion unit along the inter-pixel light-shielding wall (See, for example, Patent Document 1). In the photodetection device described in Patent Document 1, the inter-pixel light shielding wall is formed by a trench portion opened on the front surface side of the substrate and an embedded portion embedded in the trench portion, and furthermore the p-type solid-phase diffusion layer is formed by doping a p-type impurity into the substrate from the inner side surface of the trench portion.

### CITATION LIST

### Patent Document

Patent Document 1: Japanese Patent Application Laid-Open No. 2018-148116

### SUMMARY OF THE INVENTION

### Problems to be Solved by the Invention

However, in the photodetection device described in Patent Document 1, actually, the width of the trench portion becomes narrower from the front surface side toward the back surface side of the substrate. Therefore, when the p-type solid-phase diffusion layer is formed, the amount of the p-type impurity doped in the substrate decreases from the front surface side toward the back surface side of the substrate. Therefore, the concentration of the p-type impurity contained in the p-type solid-phase diffusion layer tends to decrease from the front surface side toward the back surface side of the substrate. As a result, the concentration of the p-type impurity is low at the depth at which an n-type semiconductor region constituting the photoelectric conversion unit is located, so that the internal electric field near the pn junction portion of the photoelectric conversion unit is weakened, and there is a possibility that the saturation charge amount of the photoelectric conversion unit decreases.

In contrast, the concentration of the p-type impurity contained in the p-type solid-phase diffusion layer tends to increase from the back surface side toward the front surface side of the substrate. Therefore, since the concentration of the impurity of the opposite conductivity type is high at the depth where pixel transistors such as a transfer transistor and a reset transistor are located, a strong electric field is generated in the pixel transistors, and there is a possibility that dark current characteristics are deteriorated or white spots are generated.

Therefore, there has been a possibility that the image quality of an image obtained by the photodetection device deteriorates.

It is therefore an object of the present disclosure to provide a photodetection device and an electronic apparatus capable of obtaining an image with higher image quality.

### Solutions to Problems

A photodetection device according to the present disclosure includes: (a) a substrate; (b) a plurality of photoelectric conversion units which is arranged two-dimensionally in the substrate; and (c) a pixel separation portion which is arranged between the plurality of photoelectric conversion units adjacent to each other and has a trench portion, in which (d) in the substrate, a semiconductor region of an opposite conductivity type that is opposite to a conductivity type of a charge accumulation region of each of the plurality of photoelectric conversion units is formed in at least a part between each of the plurality of photoelectric conversion units and the pixel separation portion, (e) a width of the trench portion is different for each of a plurality of regions obtained by dividing the substrate along a thickness direction, and in a region where the semiconductor region of the opposite conductivity type is formed, the region being one of the plurality of regions, the width of the trench portion is greater in a first region than in a second region, the first region being a region on a side of a surface of the substrate opposite to a light receiving surface of the substrate, and the second region being a region on a side closer to the light receiving surface of the substrate than the first region is, and (f) a concentration of an impurity of the opposite conductivity type included in a part located at an interface with the pixel separation portion in the semiconductor region of the opposite conductivity type is lower in the first region than in the second region.

An electronic apparatus according to the present disclosure includes: a photodetection device including (a) a substrate, (b) a plurality of photoelectric conversion units which is arranged two-dimensionally in the substrate, and (c) a pixel separation portion which is arranged between the plurality of photoelectric conversion units adjacent to each other and has a trench portion, in which (d) in the substrate, a semiconductor region of an opposite conductivity type that is opposite to a conductivity type of a charge accumulation region of each of the plurality of photoelectric conversion units is formed in at least a part between each of the plurality of photoelectric conversion units and the pixel separation portion, (e) a width of the trench portion is different for each of a plurality of regions obtained by dividing the substrate along a thickness direction, and in a region where the semiconductor region of the opposite conductivity type is formed, the region being one of the plurality of regions, the width of the trench portion is greater in a first region than in a second region, the first region being a region on a side of a surface of the substrate opposite to a light receiving surface of the substrate, and the second region being a region on a side closer to the light receiving surface of the substrate than the first region is, and (f) the concentration of an impurity of the opposite conductivity type included in a part located at an interface with the pixel separation portion in the semiconductor region of the opposite conductivity type is lower in the first region than in the second region.

### BRIEF DESCRIPTION OF DRAWINGS

FIG. 1 is a diagram illustrating an overall configuration of a solid-state imaging device according to a first embodiment.

FIG. 2 is a view illustrating a cross-sectional configuration of the solid-state imaging device cut along line A-A in FIG. 1.

FIG. 3 is a view illustrating a planar configuration of a transfer transistor and the like in a case where the transfer transistor and the like are viewed from a wiring layer side.

FIG. 4 is a view illustrating a cross-sectional configuration of the solid-state imaging device in a case where the number of stages of the trench portion is one.

FIG. 5A is a view illustrating a method for forming the trench portion and a semiconductor region of an opposite conductivity type.

FIG. 5B is a view illustrating the method for forming the trench portion and the semiconductor region of the opposite conductivity type.

FIG. 5C is a view illustrating the method for forming the trench portion and the semiconductor region of the opposite conductivity type.

FIG. 5D is a view illustrating the method for forming the trench portion and the semiconductor region of the opposite conductivity type.

FIG. 5E is a view illustrating the method for forming the trench portion and the semiconductor region of the opposite conductivity type.

FIG. 5F is a view illustrating the method for forming the trench portion and the semiconductor region of the opposite conductivity type.

FIG. 5G is a view illustrating the method for forming the trench portion and the semiconductor region of the opposite conductivity type.

FIG. 5H is a view illustrating the method for forming the trench portion and the semiconductor region of the opposite conductivity type.

FIG. 5I is a view illustrating the method for forming the trench portion and the semiconductor region of the opposite conductivity type.

FIG. 5J is a view illustrating the method for forming the trench portion and the semiconductor region of the opposite conductivity type.

FIG. 5K is a view illustrating the method for forming the trench portion and the semiconductor region of the opposite conductivity type.

FIG. 5L is a view illustrating the method for forming the trench portion and the semiconductor region of the opposite conductivity type.

FIG. 5M is a view illustrating the method for forming the trench portion and the semiconductor region of the opposite conductivity type.

FIG. 5N is a view illustrating the method for forming the trench portion and the semiconductor region of the opposite conductivity type.

FIG. 6 is a view illustrating an overall configuration of a solid-state imaging device according to a modification.

FIG. 7 is a view illustrating a cross-sectional configuration of a solid-state imaging device according to a modification.

FIG. 8 is a view illustrating a cross-sectional configuration of a solid-state imaging device according to a modification.

FIG. 9 is a view illustrating an entire configuration of a solid-state imaging device according to a modification.

FIG. 10 is a view illustrating an entire configuration of a solid-state imaging device according to a modification.

FIG. 11 is a view illustrating an entire configuration of a solid-state imaging device according to a modification.

FIG. 12 is a view illustrating an entire configuration of a solid-state imaging device according to a modification.

FIG. 13 is a schematic configuration diagram of an electronic apparatus according to a second embodiment.

### MODE FOR CARRYING OUT THE INVENTION

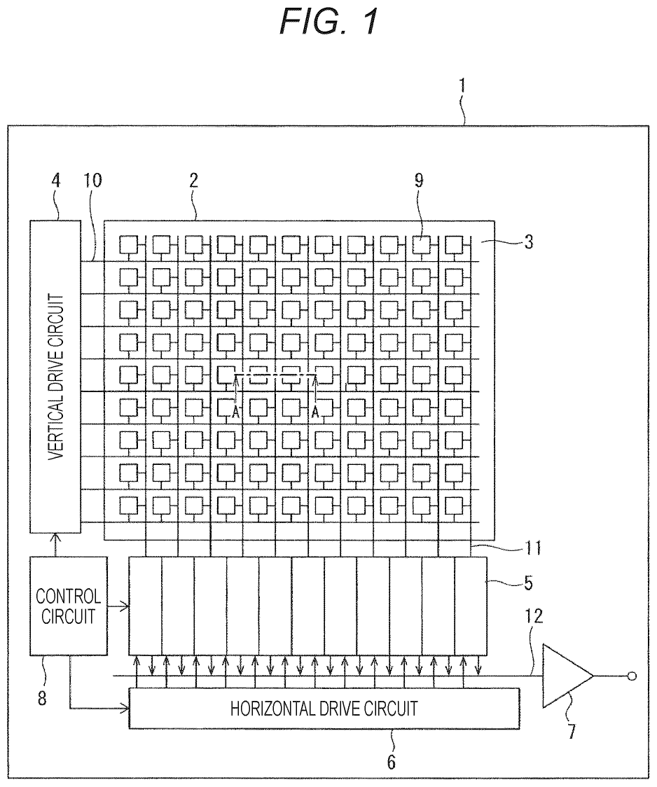

Hereinafter, an example of a photodetection device and an electronic apparatus according to embodiments of the present disclosure will be described with reference to FIGS. 1 to 13. The embodiments of the present disclosure will be described in the following order. Note that, the present disclosure is not limited to the following examples. Furthermore, the effects described in the present specification are illustrative and not restrictive, and there may be additional effects.
1. First Embodiment: Solid-State Imaging Device
1-1 Overall Configuration of Solid-State Imaging Device
1-2 Configuration of Main Part
1-3 Method for Forming Trench Portion and Semiconductor Region of Opposite Conductivity Type
1-4 Modifications
2. Second Embodiment: Application Example to Electronic Apparatus

### 1. First Embodiment: Solid-State Imaging Device

### [1-1 Overall Configuration of Solid-State Imaging Device]

A solid-state imaging device 1 (in a broad sense, a “photodetection device”) according to a first embodiment of the present disclosure will be described. FIG. 1 is a diagram illustrating an overall configuration of the solid-state imaging device 1 according to the first embodiment.

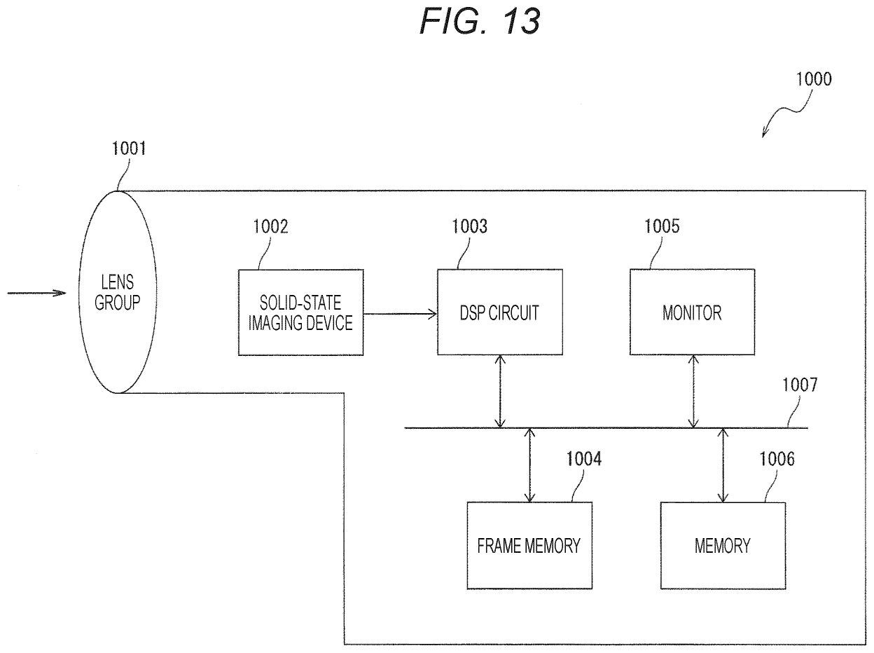

The solid-state imaging device 1 in FIG. 1 is a back-illuminated complementary metal oxide semiconductor (CMOS) image sensor. As illustrated in FIG. 13, the solid-state imaging device 1 (1002) captures image light (incident light) from a subject via a lens group 1001, converts an amount of the incident light an image of which is formed on an imaging surface into an electric signal for each pixel, and outputs the electric signal as a pixel signal.

As illustrated in FIG. 1, the solid-state imaging device 1 includes a substrate 2, a pixel region 3, a vertical drive circuit 4, a column signal processing circuit 5, a horizontal drive circuit 6, an output circuit 7, and a control circuit 8.

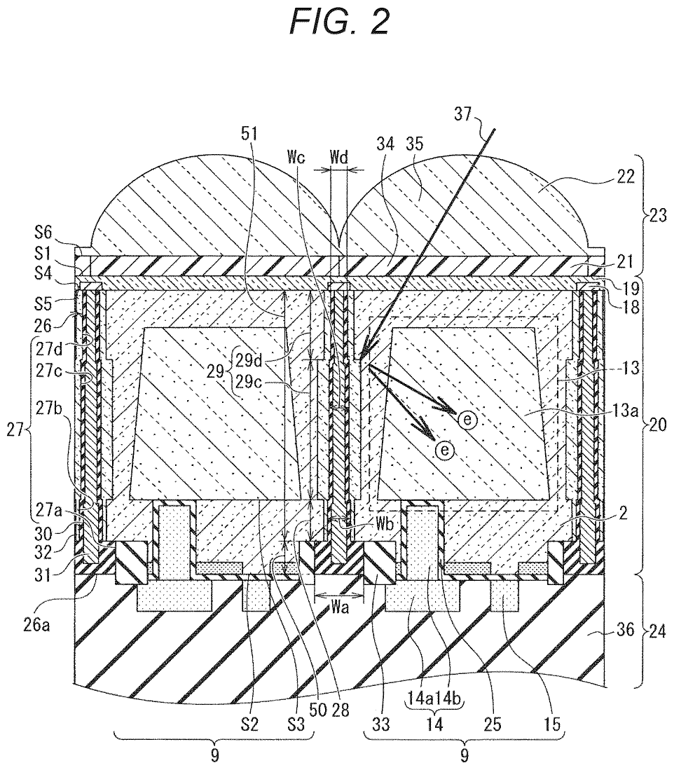

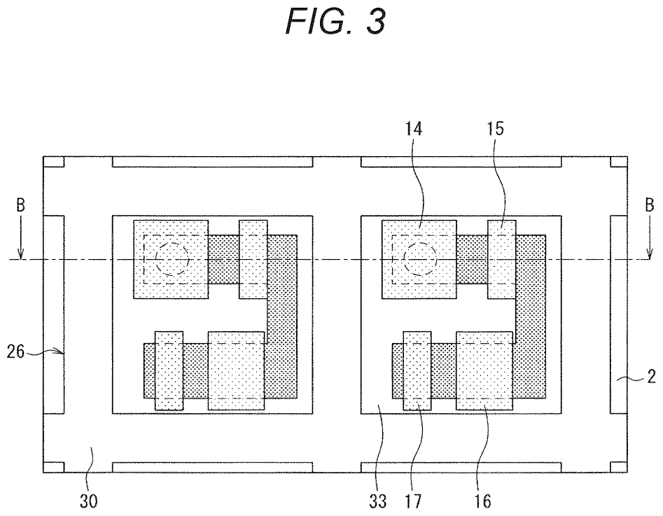

The pixel region 3 includes a plurality of pixels 9 regularly arrayed in a two-dimensional array on the substrate 2. The pixel 9 includes a photoelectric conversion unit 13 illustrated in FIGS. 2, and 3, and a plurality of pixel transistors. As the plurality of pixel transistors, a transfer transistor 14, a reset transistor 15, an amplification transistor 16, and a selection transistor 17 can be employed, for example.

The vertical drive circuit 4 includes, for example, a shift register, selects desired pixel drive wiring 10, supplies a pulse for driving the pixel 9 to the selected pixel drive wiring 10, and drives the pixels 9 row by row. That is, the vertical drive circuit 4 sequentially selects and scans the pixels 9 in the pixel region 3 row by row in the vertical direction, and supplies a pixel signal based on the signal charge generated according to the amount of received light in the photoelectric conversion unit 13 of each pixel 9 through a vertical signal line 11 to the column signal processing circuit 5.

The column signal processing circuit 5 is arranged, for example, for each column of the pixels 9, and performs signal processing such as noise removal on signals output from the pixels 9 in one row for each pixel column. For example, the column signal processing circuit 5 performs signal processing such as correlated double sampling (CDS) for removing a pixel-specific fixed pattern noise, and analog-digital (AD) conversion.

The horizontal drive circuit 6 includes, for example, a shift register, sequentially outputs a horizontal scanning pulse to the column signal processing circuits 5, sequentially selects each of the column signal processing circuits 5, and causes each of the column signal processing circuits 5 to output the pixel signal subjected to the signal processing to a horizontal signal line 12.

The output circuit 7 performs signal processing on the pixel signals sequentially supplied from the respective column signal processing circuits 5 through the horizontal signal line 12, and outputs the signals subjected to signal processing. As the signal processing, for example, buffering, black level adjustment, column variation correction, various types of digital signal processing and the like can be used.

The control circuit 8 generates a clock signal and a control signal serving as a reference of operations of the vertical drive circuit 4, the column signal processing circuit 5, the horizontal drive circuit 6, and the like on the basis of a vertical synchronization signal, a horizontal synchronization signal, and a master clock signal. Then, the control circuit 8 outputs the generated clock signal and control signal to the vertical drive circuit 4, the column signal processing circuits 5, the horizontal drive circuit 6, and the like.

### [1-2 Configuration of Main Part]

Next, a detailed structure of the solid-state imaging device 1 is described. FIG. 2 is a view illustrating a cross-sectional configuration of the solid-state imaging device 1 taken along line A-A in FIG. 1. Furthermore, FIG. 2 is also a view illustrating a cross-sectional configuration of the solid-state imaging device 1 taken along line B-B in FIG. 3. FIG. 3 is a view illustrating a planar configuration of the transfer transistor 14 and the like in a case where the transfer transistor 14 and the like are viewed from the wiring layer 24 side.

As illustrated in FIG. 2, in the solid-state imaging device 1, a light receiving layer 20 formed by stacking the substrate 2, a light shielding film 18, and a planarization film 19 in this order is arranged. Furthermore, a light condensing layer 23 in which a color filter array 21 and a microlens array 22 are stacked in this order is formed on a surface (hereinafter, also referred to as a “back surface S1”) of the light receiving layer 20 on the planarization film 19 side. Moreover, a wiring layer 24 is arranged on a surface (hereinafter, also referred to as a “front surface S2”) of the light receiving layer 20 on the substrate 2 side.

The substrate 2 includes, for example, a semiconductor substrate containing silicon (Si), and forms the pixel region 3. In the pixel region 3, the plurality of pixels 9 each including the photoelectric conversion unit 13, and four pixel transistors including the transfer transistor 14, the reset transistor 15, the amplification transistor 16 illustrated in FIG. 3, and the selection transistor 17 illustrated in FIG. 3 is arranged in a two-dimensional array. The photoelectric conversion unit 13 includes a p-type semiconductor region formed on the outer peripheral side and an n-type semiconductor region formed on the central portion side and forms a photodiode by pn junction. As a result, each of the photoelectric conversion units 13 generates a signal charge corresponding to an amount of incident light on the photoelectric conversion unit 13, and accumulates the generated signal charge in the n-type semiconductor region (a charge accumulation region 13a).

Furthermore, the pixel transistors (the transfer transistor 14, the reset transistor 15, the amplification transistor 16, and the selection transistor 17) are formed on the front surface S2 of the substrate 2 (in a broad sense, the surface opposite to the light receiving surface of the substrate 2). The transfer transistor 14 includes a planar gate electrode 14a formed on the front surface S2 of the substrate 2 and a vertical gate electrode 14b which has a columnar shape and extends from the front surface S2 of the substrate 2 toward the photoelectric conversion unit 13 under the planar gate electrode 14a. An end of the vertical gate electrode 14b on the photoelectric conversion unit 13 side reaches a surface (hereinafter, also referred to as “front surface S3”) of the charge accumulation region 13a of the photoelectric conversion unit 13 on the wiring layer 24 side via a gate insulating film 25.

Furthermore, in the substrate 2, a pixel separation portion 26 is formed between the adjacent photoelectric conversion units 13. The pixel separation portion 26 is formed from the front surface S2 to the light receiving surface (hereinafter, also referred to as a “back surface S4”) of the substrate 2 along the side surface of the photoelectric conversion unit 13. Then, in a case of being viewed from the microlens array 22 side, the pixel separation portion 26 is formed in a lattice shape so as to surround the periphery of each photoelectric conversion unit 13. The pixel separation portion 26 includes a trench portion 27 in which an opening is formed on the front surface S2 of the substrate 2 and a surface of the planarization film 19 on the substrate 2 side (hereinafter, also referred to as a “front surface S5”) is the bottom surface. The trench portion 27 is formed into a lattice shape in such a manner that the inner side surfaces become the outer peripheral portion of the pixel separation portion 26.

The width of the trench portion 27 is different for each of a plurality of regions obtained by dividing the substrate 2 along the thickness direction. FIG. 2 illustrates a case where a region (hereinafter, a “front surface-side region 50”) on the front surface S2 side of the substrate 2 and a region (a region where a semiconductor region 32 of an opposite conductivity type to be described later is formed. Hereinafter, also referred to as a “back surface-side region 51”) on the back surface S4 side of the substrate 2 are provided as the plurality of regions. The back surface-side region 51 includes a region (hereinafter, also referred to as a “first region 28”) on the front surface S2 side (the side of the surface opposite to the light receiving surface) of the substrate 2 and a region (region on the side of the light receiving surface of the substrate 2. Hereinafter, also referred to as a “second region 29”) on the side closer to the back surface S4 than the first region 28 is. Furthermore, the second region 29 includes a region located on the first region 28 side (hereinafter, also referred to as a “third region 29c”) and a region located on the side far from the first region 28 (hereinafter, also referred to as a “fourth region 29d”). In FIG. 2, the magnitude relationship of the width of the trench portion 27 is as follows: the width Wa of the trench portion 27 in the front surface-side region 50>the width Wb of the trench portion 27 in the first region 28>the width Wc of the trench portion 27 in the third region 29c>the width Wd of the trench portion 27 in the fourth region 29d. That is, the width of the trench portion 27 is gradually narrowed from the front surface S2 side (side of the surface opposite to the light receiving surface) of the substrate 2 toward the back surface S4 side (side of the light receiving surface). As a result, the width of the trench portion 27 is larger in the first region 28 than in the second region 29 (Wb>Wc, Wd). By satisfying Wa>Wb>Wc>Wd (Wb>Wc, Wd), the light receiving surface of the photoelectric conversion unit 13 can be enlarged.

Specifically, the trench portion 27 includes four stages of trench portions (hereinafter, also referred to as a “first trench portion 27a”, a “second trench portion 27b”, a “third trench portion 27c”, and a “fourth trench portion 27d” having different widths Wa, Wb, Wc, and Wd, respectively, in a cross section perpendicular to the back surface S4 (light receiving surface) of the substrate 2. The first trench portion 27a is a trench portion having an opening on the front surface S2 of the substrate 2 and extending in a direction perpendicular to the front surface S2 of the substrate 2. Furthermore, the second trench portion 27b is a trench portion having an opening on the bottom surface of the first trench portion 27a and extending in the direction perpendicular to the front surface S2 of the substrate 2. Furthermore, the third trench portion 27c is a trench portion having an opening on the bottom surface of the second trench portion 27b and extending in the direction perpendicular to the front surface S2 of the substrate 2. Furthermore, the fourth trench portion 27d is a trench portion having openings on the bottom surface of the third trench portion 27c and the back surface S4 of the substrate 2 and extending in the direction perpendicular to the front surface S2 of the substrate 2. As a result, the trench portion 27 has openings on the front surface S2 and the back surface S4 of the substrate 2, and extends in the direction perpendicular to the front surface S2 of the substrate 2 to penetrate the substrate 2. With the configuration in which the trench portion 27 penetrates the substrate 2, an end 26b of the pixel separation portion 26 on the light receiving surface side reaches the back surface S4 of the substrate 2, and an end 26a opposite to the light receiving surface reaches the front surface S2 of the substrate 2.

Furthermore, in the depth direction from the front surface S2 of the substrate 2, the range where the first trench portion 27a is located is from the front surface S2 of the substrate 2 to the depth where the deepest portion of an element separation portion 33 described later is located. Furthermore, the range where the second trench portion 27b is located is from the depth where the deepest portion of the element separation portion 33 is located to the depth where the front surface S3 of the charge accumulation region 13a is located. Furthermore, the range where the third trench portion 27c is located is from the depth where the front surface S3 of the charge accumulation region 13a is located to the depth where a part of the charge accumulation region 13a on the microlens array 22 side is located. Furthermore, the range where the fourth trench portion 27d is located is from the depth where the part of the charge accumulation region 13a on the microlens array 22 side is located to the back surface S4 of the substrate 2. As a result, in the depth direction from the front surface S2 of the substrate 2, the range where the second region 29 is located overlaps at least partially with the range where the charge accumulation region 13a is located.

Furthermore, the inner side surfaces and the opening of the trench portion 27 (the first trench portion 27a, the second trench portion 27b, the third trench portion 27c, and the fourth trench portion 27d) are covered with an insulating film 30. As a material of the insulating film 30, for example, silicon oxide (SiO₂) can be employed. Furthermore, an embedded portion 31 is embedded in the trench portion 27. As the embedded portion 31, for example, aluminum (Al), doped polysilicon (Poly-Si), or silicon oxide (SiO₂) can be employed. As a result, in a case where light incident on the photoelectric conversion unit 13 enters the pixel separation portion 26, the light can be reflected at the interface between the insulating film 30 and the embedded portion 31, and optical color mixing can be suppressed.

Furthermore, in the substrate 2, the semiconductor region 32 of an opposite conductivity type (p-type) which is opposite to that of the charge accumulation region 13a of the photoelectric conversion unit 13 is formed in at least a part between the photoelectric conversion unit 13 and the pixel separation portion 26. FIG. 2 illustrates a case where the semiconductor region 32 of the opposite conductivity type is formed from the front surface S2 of the substrate 2 to the boundary surface between the back surface-side region 51 and the front surface-side region 50 along the surface of the pixel separation portion 26 on the photoelectric conversion unit 13 side. The semiconductor region 32 of the opposite conductivity type is formed in a frame shape so as to surround each of the photoelectric conversion units 13 as viewed from the microlens array 22 side. As the impurity constituting the semiconductor region 32 of the opposite conductivity type, for example, boron (B) can be adopted. As a result, the hole concentration in the region adjacent to the pixel separation portion 26 (trench portion 27) can be increased, electrons generated due to a defect generated at the time of forming the trench portion 27 can be recombined with the holes, and it is possible to suppress the electrons from being detected by the photoelectric conversion unit 13 and becoming a dark current or a white spot.

The magnitude relationship of the concentration of the impurity of the opposite conductivity type included in the portion (hereinafter, also referred to as an “interface portion”) located at the interface with the pixel separation portion 26 in the semiconductor region 32 of the opposite conductivity type is: concentration Cb of the first region 28<concentration Cd of the fourth region 29d<concentration Cc of the third region 29c. That is, the concentration of the impurity of the opposite conductivity type included in the interface portion is lower in the first region 28 than in the second region 29 (Cb<Cc, Cd). Similarly, the concentration of the impurity of the opposite conductivity type included in the interface portion is lower in the fourth region 29d than in the third region 29c (Cd<Cc). By setting the concentration Cb of the first region 28 in the interface portion to be relatively low, the electric field generated in the pixel transistor can be alleviated, and deterioration of dark current characteristics and white spots can be suppressed. Furthermore, by making the concentrations Cc and Cd of the second region 29 in the interface portion relatively higher, pinning can be enhanced (a high hole concentration state can be achieved) at the interface between the photoelectric conversion unit 13 and the pixel separation portion 26, and deterioration of dark current characteristics and white spots can be suppressed.

Furthermore, since Cd<Cc, a decrease in the volume of the charge accumulation region 13a in the fourth region 29d (near the back surface S4) can be suppressed, and a decrease in the saturation charge amount of the photoelectric conversion unit 13 can be suppressed.

Here, the impurity of the opposite conductivity type constituting the semiconductor region 32 of the opposite conductivity type is doped into the substrate 2 from the inner side surface side of the trench portion 27. Therefore, the concentration of the impurity in the semiconductor region 32 of the opposite conductivity type is maximized in a portion (interface portion) located at the interface with the pixel separation portion 26, and decreases from the interface portion side toward the photoelectric conversion unit 13 side. Therefore, in FIG. 2, the width (that is, the thickness in the width direction of the trench portion 27) of the semiconductor region 32 of the opposite conductivity type increases as the concentration of the impurity in the interface portion increases. That is, the magnitude relationship of the width of the semiconductor region 32 of the opposite conductivity type is that the width of the semiconductor region 32 of the opposite conductivity type in the first region 28<the width of the semiconductor region 32 of the opposite conductivity type in the fourth region 29d<the width of the semiconductor region 32 of the opposite conductivity type in the third region 29c.

Furthermore, in the substrate 2, the element separation portion 33 is formed from the front surface S2 of the substrate 2 to a predetermined depth. The element separation portion 33 is formed to fill the front surface S2 so as to surround the periphery of each of the pixel transistors such as the transfer transistor 14 and the reset transistor 15 as viewed from the wiring layer 24 side. As a result, the element separation portion 33 is in contact with the surface of the pixel separation portion 26 on the photoelectric conversion unit 13 side. FIG. 2 illustrates a case where a depth about half of the vertical gate electrode 14b is used as the predetermined depth. That is, in the depth direction from the front surface S2 of the substrate 2, the range where the element separation portion 33 is located overlaps at least partially with the range where the vertical gate electrode 14b is located. As a result, the semiconductor region 32 of the opposite conductivity type can be omitted from the front surface S2 side of the substrate 2, and the electric field generated in the pixel transistor due to the semiconductor region 32 of the opposite conductivity type can be relaxed. FIG. 2 illustrates a case where a shallow trench isolation (STI) structure in which a groove is formed in the front surface of the substrate 2 and an insulating material is embedded in the groove is used as the structure of the element separation portion 33. Note that as the structure of the element separation portion 33, for example, a concealed isolation with oxide burying nick (CION) structure in which an impurity is implanted into the substrate 2 can also be employed.

The light shielding film 18 is formed in a lattice shape so as to open the light receiving surface of each of the plurality of photoelectric conversion units 13 in a part (a part on the light receiving surface side) on the back surface S4 side of the substrate 2. That is, the light shielding film 18 is formed at a location overlapping the pixel separation portion 26 formed in a lattice shape. As a material of the light shielding film 18, for example, aluminum (Al), tungsten (W), or copper (Cu) can be adopted.

The planarization film 19 continuously covers the entire back surface S4 side (the entire light receiving surface side) of the substrate 2 including the light shielding film 18. As a result, the back surface S1 of the light receiving layer 20 is a flat surface without unevenness. As a material of the planarization film 19, for example, an organic material such as resin can be used.

The color filter array 21 is formed on the back surface S1 side of the planarization film 19 and includes a plurality of color filters 34 arranged corresponding to the photoelectric conversion units 13. That is, one color filter 34 is formed for one photoelectric conversion unit 13. The plurality of color filters 34 includes a plurality of types of color filters which each transmit light of a predetermined wavelength included in the light collected by a microlens 35. Therefore, each of the plurality of color filters 34 transmits light of a predetermined wavelength corresponding to the color filter 34, and causes the transmitted light to be incident on the photoelectric conversion unit 13.

The microlens array 22 is formed on a back surface S6 side (light receiving surface side) of the color filter array 21, and includes the plurality of microlenses 35 arranged corresponding to the photoelectric conversion units 13. That is, one microlens 35 is formed for one photoelectric conversion unit 13. Therefore, each of the microlenses 35 condenses image light (incident light) from a subject, and allows the condensed incident light to enter the corresponding photoelectric conversion unit 13 via the color filter 34.

The wiring layer 24 is formed on the front surface S2 side of the substrate 2, and includes an interlayer insulating film 36 and a plurality of layers of wiring (not illustrated) stacked with the interlayer insulating film 36 interposed therebetween. Then, the wiring layer 24 drives the pixel transistors forming each pixel 9 via the plurality of layers of wiring.

In the solid-state imaging device 1 having the above configuration, light is emitted from the back surface S4 side of the substrate 2, the emitted light passes through the microlens 35 and the color filter 34, and the transmitted light is photoelectrically converted by the photoelectric conversion unit 13 to generate a signal charge. Then, the generated signal charge is output as the pixel signal by the vertical signal line 11 in FIG. 1, formed by using the wiring of the wiring layer 24.

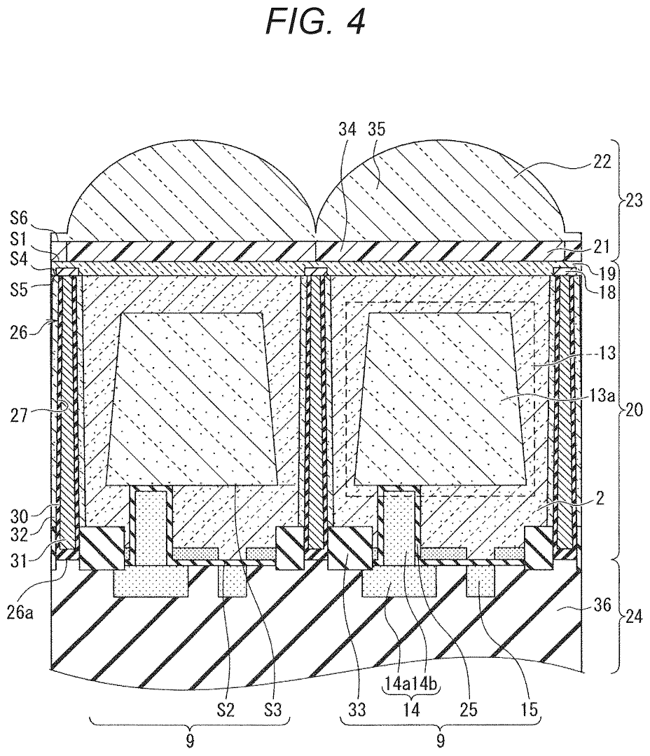

Here, for example, as illustrated in FIG. 4, in a case where the number of stages of the trench portions 27 is one, the width of the trench portion 27 becomes narrower from the front surface S2 side toward the back surface S4 side of the substrate 2. Therefore, for example, when the substrate 2 is doped with an impurity from the inside of the trench portion 27 to form the semiconductor region 32 of the opposite conductivity type around the trench portion 27, the amount of impurity doped in the substrate 2 decreases from the front surface S2 side toward the back surface S4 side of the substrate 2. Therefore, the concentration of the impurity of the opposite conductivity type included in the portion located at the interface with the pixel separation portion 26 in the semiconductor region 32 of the opposite conductivity type (p-type) decreases from the front surface S2 side toward the back surface S4 side of the substrate 2. As a result, the concentration of the impurity of the opposite conductivity type is low at the depth at which the charge accumulation region 13a (n-type semiconductor region) constituting the photoelectric conversion unit 13 is located, so that the internal electric field near the pn junction portion of the photoelectric conversion unit 13 is weakened, and there is a possibility that the saturation charge amount of the photoelectric conversion unit 13 decreases.

In contrast, the concentration of the impurity of the opposite conductivity type (p-type) included in the portion located at the interface with the pixel separation portion 26 in the semiconductor region 32 of the opposite conductivity type (p-type) increases from the back surface S4 side toward the front surface S2 side of the substrate 2. Therefore, since the concentration of the impurity of the opposite conductivity-type is high at the depth where the pixel transistors such as the transfer transistor 14 and the reset transistor 15 is located, a strong electric field is generated in the pixel transistors, and there is a possibility that dark current characteristics are deteriorated or white spots may be generated.

Therefore, there is a possibility that the image quality of an image obtained by the solid-state imaging device 1 deteriorates.

In contrast, in the solid-state imaging device 1 according to the first embodiment, the concentration of the impurity of the opposite conductivity type (p-type) included in the portion located at the interface with the pixel separation portion 26 in the semiconductor region 32 of the opposite conductivity type (p-type) is lower in the first region 28 (region located on the front surface S2 side of the substrate 2) than in the second region 29 (region located on the side closer to the back surface S4 than the first region 28 is). As a result, the concentration of the impurity of the opposite conductivity type is low at the depth where the pixel transistors such as the transfer transistor 14 and the reset transistor 15 are located. Therefore, it is possible to relax the electric field generated in the pixel transistors, and it is possible to lower the likelihood that dark current characteristics are deteriorated or white spots are generated.

In contrast, the concentration of the impurity of the opposite conductivity type (p-type) is high at the depth at which the charge accumulation region 13a (n-type semiconductor region) constituting the photoelectric conversion unit 13 is located, so that the internal electric field near the pn junction portion of the photoelectric conversion unit 13 can be increased, and reduction in the saturation charge amount of the photoelectric conversion unit 13 can be suppressed.

Furthermore, in the solid-state imaging device 1 according to the first embodiment, the width of the trench portion 27 is larger in the first region 28 than in the second region 29. As a result, corner portions each formed by a step is generated between the second trench portion 27b and the third trench portion 27c and between the third trench portion 27c and the fourth trench portion 27d. Therefore, as illustrated in FIG. 2, in a case where the light incident on the photoelectric conversion unit 13 hits the corner portion, incident light 37 hitting the corner portion can be diffused, and the optical path length of the incident light 37 can be increased. Therefore, light having a long wavelength (for example, near infrared light and far infrared light) included in the incident light 37 can be more reliably photoelectrically converted, and sensitivity to light having a long wavelength can be improved.

Therefore, it is possible to provide the solid-state imaging device 1 capable of obtaining an image with higher image quality.

### [1-3 Method for Forming Trench Portion and Semiconductor Region of Opposite Conductivity Type]

Next, a method for forming the trench portion 27 and the semiconductor region 32 of the opposite conductivity type will be described.

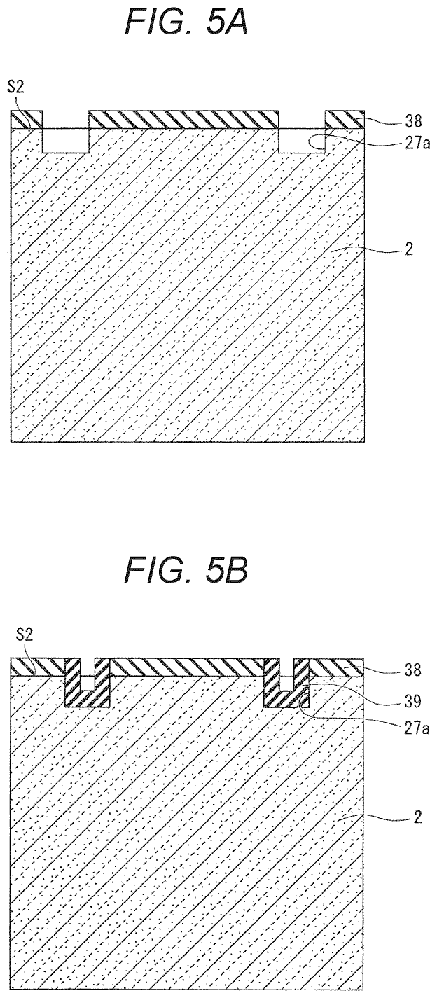

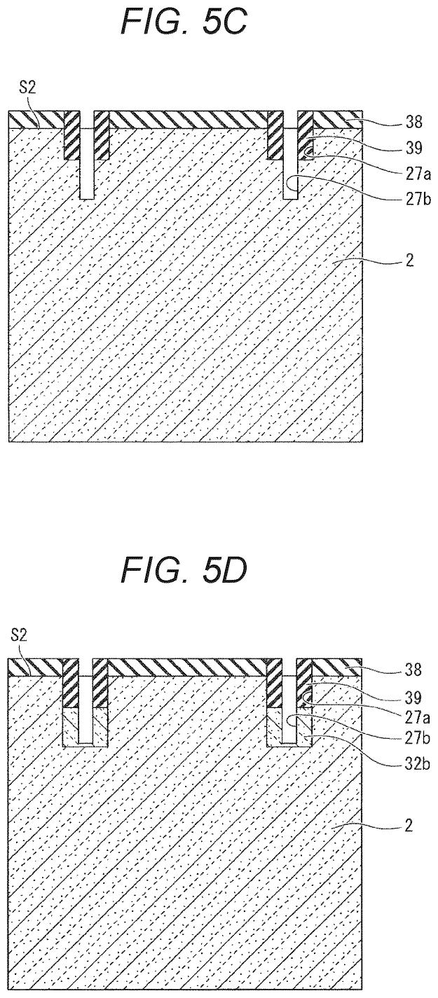

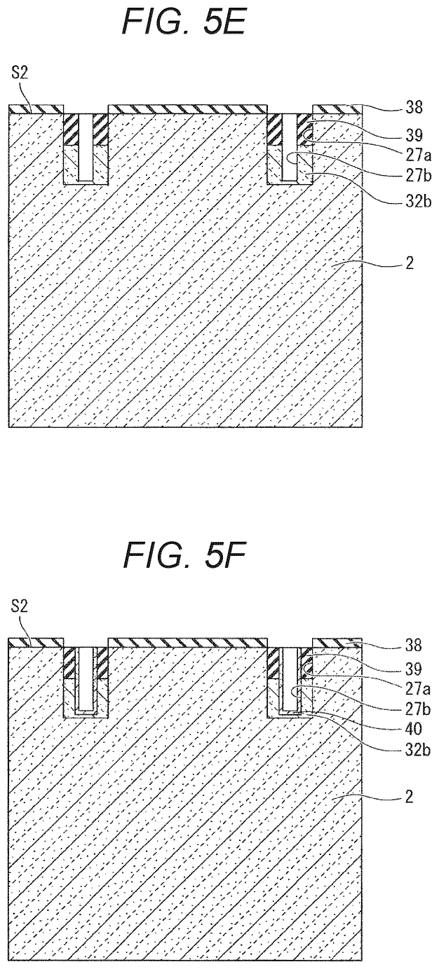

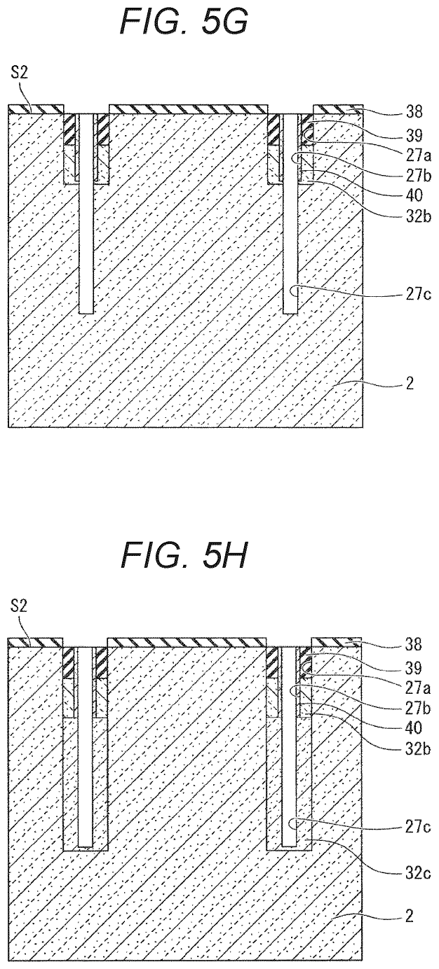

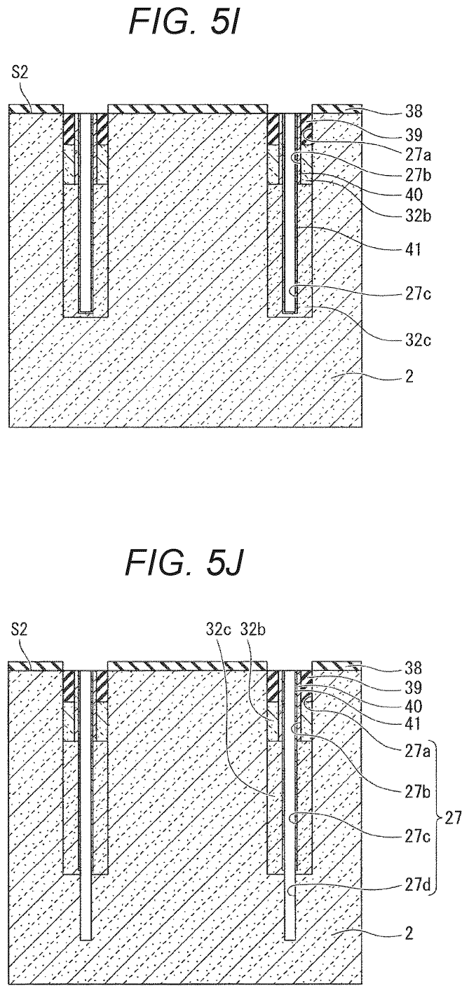

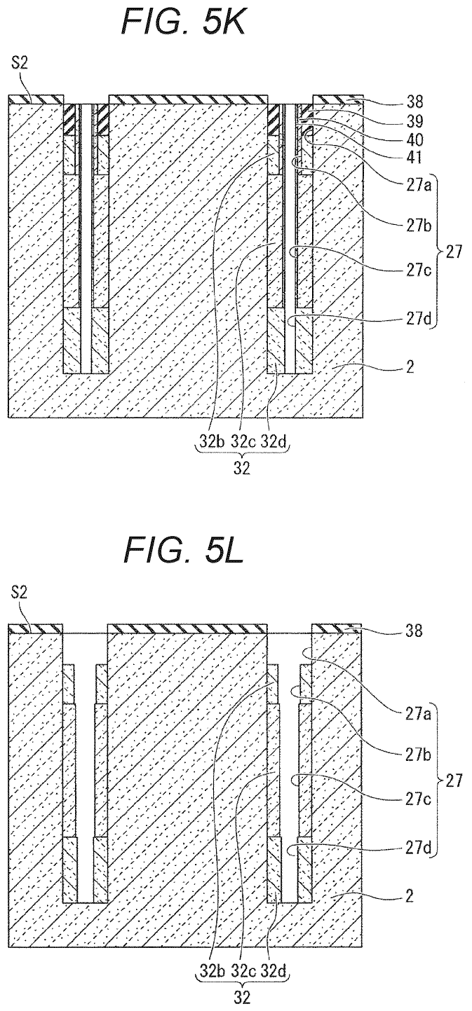

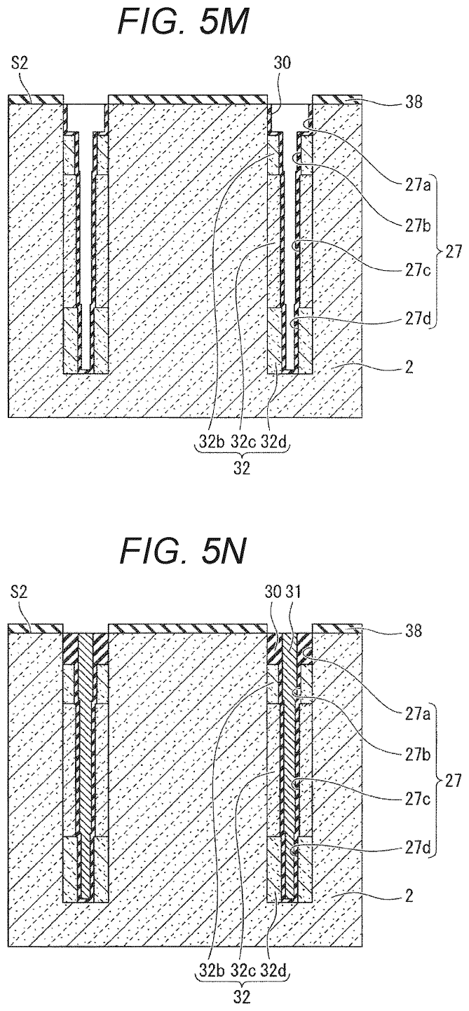

First, as illustrated in FIG. 5A, a hard mask 38 having an opening at a location where the first trench portion 27a is to be formed is formed on the front surface S2 of the substrate 2. Subsequently, anisotropic dry etching is performed via the hard mask 38 to form the first trench portion 27a. Subsequently, as illustrated in FIG. 5B, an oxide film 39 is formed on the inner side surfaces and the bottom surface of the first trench portion 27a. Subsequently, as illustrated in FIG. 5C, anisotropic dry etching (for example, RIE) is performed to form the second trench portion 27b in the bottom surface of the first trench portion 27a.

Subsequently, an impurity is doped into the substrate 2 from the inside of the second trench portion 27b, and as illustrated in FIG. 5D, a semiconductor region 32b of the opposite conductivity type (p-type) is formed around the second trench portion 27b. The semiconductor region 32b and semiconductor regions 32c and 32d described later are a part of the semiconductor region 32 illustrated in FIG. 2. Examples of the method for doping an impurity include plasma doping. In addition, for example, an ion implant injection method or a solid phase diffusion method can also be employed.

Subsequently, as illustrated in FIG. 5E, the hard mask 38 is removed from the front surface S2 of the substrate 2. FIG. 5E illustrates a case where the hard mask 38 slightly remains on the front surface S2. Subsequently, as illustrated in FIG. 5F, an oxide film 40 is continuously formed on the surface of the oxide film 39 and the inner side surfaces and the bottom surface of the second trench portion 27b. Subsequently, as illustrated in FIG. 5G, anisotropic dry etching is performed to form the third trench portion 27c on the bottom surface of the second trench portion 27b. Subsequently, an impurity is doped into the substrate 2 from the inside of the third trench portion 27c, and as illustrated in FIG. 5H, a semiconductor region 32c of the opposite conductivity type is formed around the third trench portion 27c.

Subsequently, as illustrated in FIG. 5I, an oxide film 41 is continuously formed on the surface of the oxide film 40 and the inner side surfaces and the bottom surface of the third trench portion 27c. Subsequently, as illustrated in FIG. 5J, anisotropic dry etching is performed to form the fourth trench portion 27d on the bottom surface of the third trench portion 27c. Subsequently, an impurity is doped into the substrate 2 from the inside of the fourth trench portion 27d, and as illustrated in FIG. 5K, a semiconductor region 32d of the opposite conductivity type is formed around the fourth trench portion 27d. As a result, the trench portion 27 and the semiconductor region 32 of the opposite conductivity type are formed. Subsequently, as illustrated in FIG. 5L, the oxide films 39, 40, and 41 are removed from the inner side surfaces of the trench portion 27. Subsequently, as illustrated in FIG. 5M, the insulating film 30 is formed on the inner side surfaces of the trench portion 27.

Subsequently, as illustrated in FIG. 5N, the embedded portion 31 is embedded in the trench portion 27 to form the pixel separation portion 26. Subsequently, the charge accumulation region 13a of the photoelectric conversion unit 13 is formed to form the photoelectric conversion unit 13. Subsequently, the pixel transistors such as the transfer transistor 14 and the reset transistor 15 are formed on the front surface S2 side of the substrate 2. Subsequently, the wiring layer 24 is formed on the front surface S2 of the substrate 2. As a result, the solid-state imaging device 1 according to the first embodiment is manufactured.

Here, for example, when a method of introducing an impurity by plasma doping from the front surface S2 side of the substrate 2 at the time of forming the semiconductor regions 32b and 32c of the opposite conductivity type is employed, the width of the semiconductor region 32 of the opposite conductivity type is widened. Therefore, the charge accumulation region 13a (n-type semiconductor region) of the photoelectric conversion unit 13 becomes small, and there is a possibility that the saturation charge amount of the photoelectric conversion unit 13 becomes small.

In contrast, in the solid-state imaging device 1 according to the first embodiment, an impurity is doped into the substrate 2 from the inside of the second trench portion 27b and the third trench portion 27c. Therefore, it is possible to suppress the impurity from spreading in a direction parallel to the front surface S2 of the substrate 2 from the front surface S2 side toward the back surface S4 side of the substrate 2. Therefore, it is possible to control the concentration of the impurity in the semiconductor region 32 of the opposite conductivity type (p-type) while suppressing the reduction in the saturation charge amount of the photoelectric conversion unit 13. As a result, the degree of freedom in designing the concentration of the impurity in the semiconductor region 32 of the opposite conductivity type (p-type) can be improved.

### [1-4 Modifications]

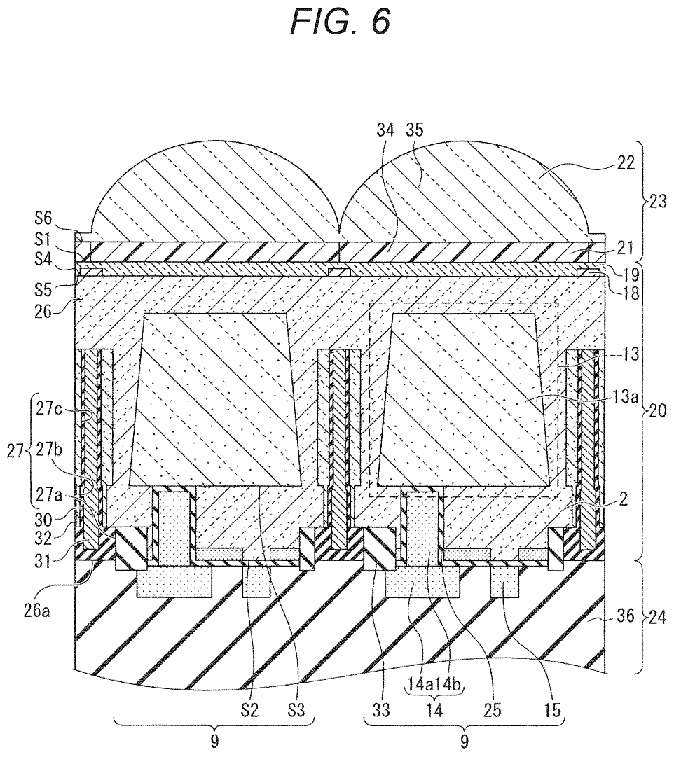

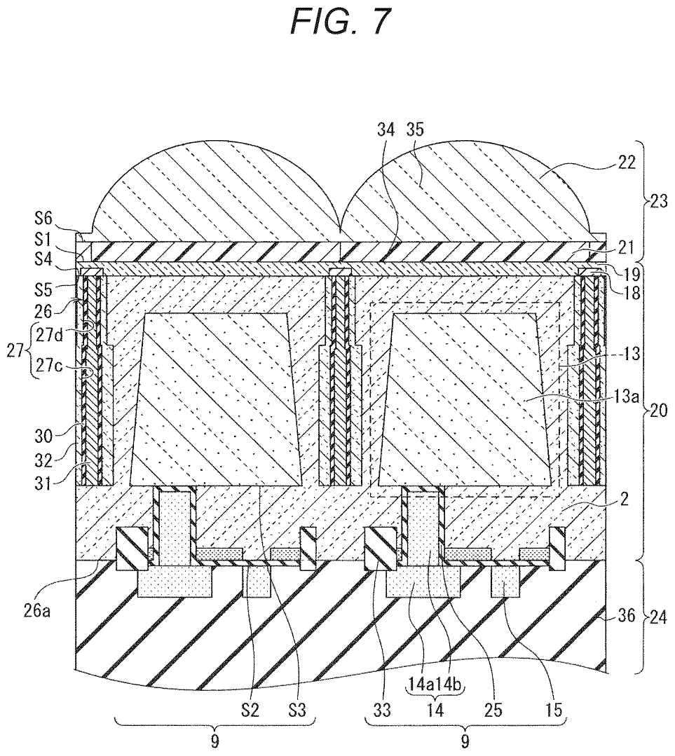

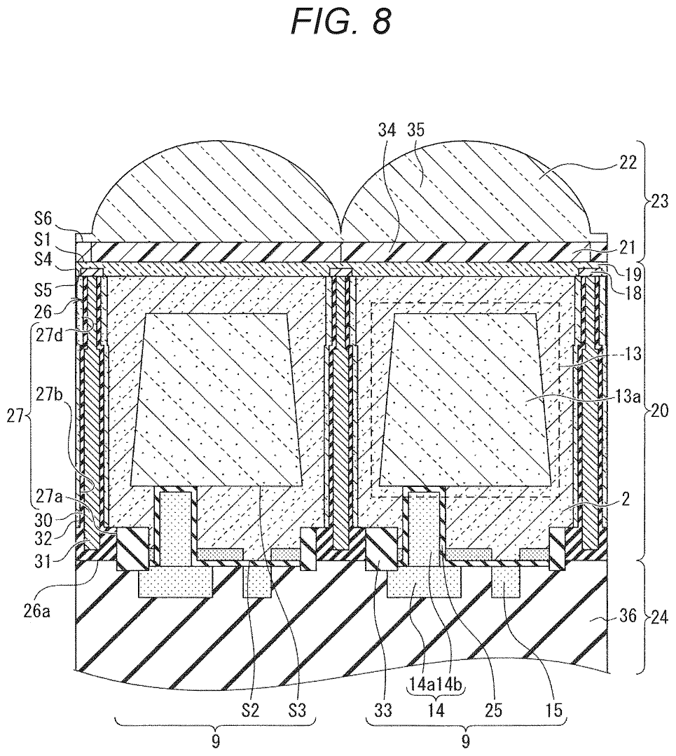

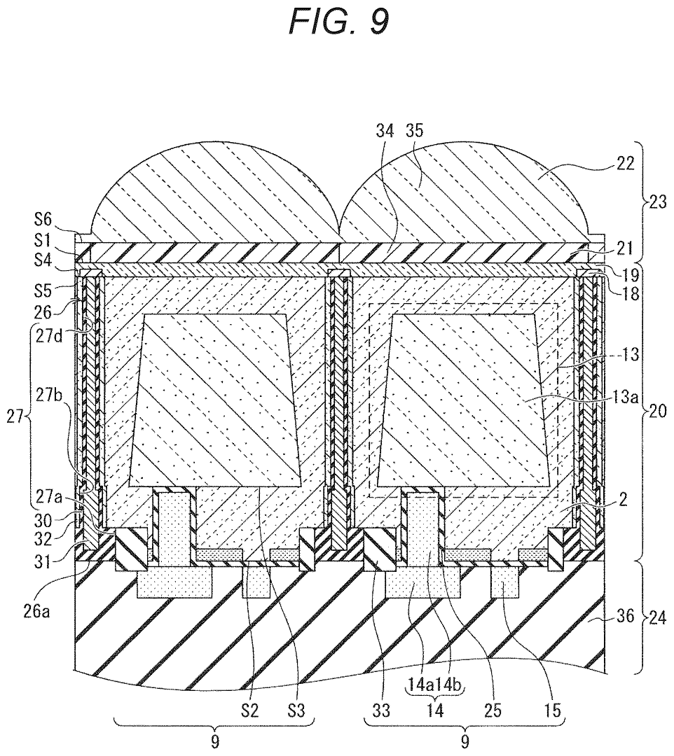

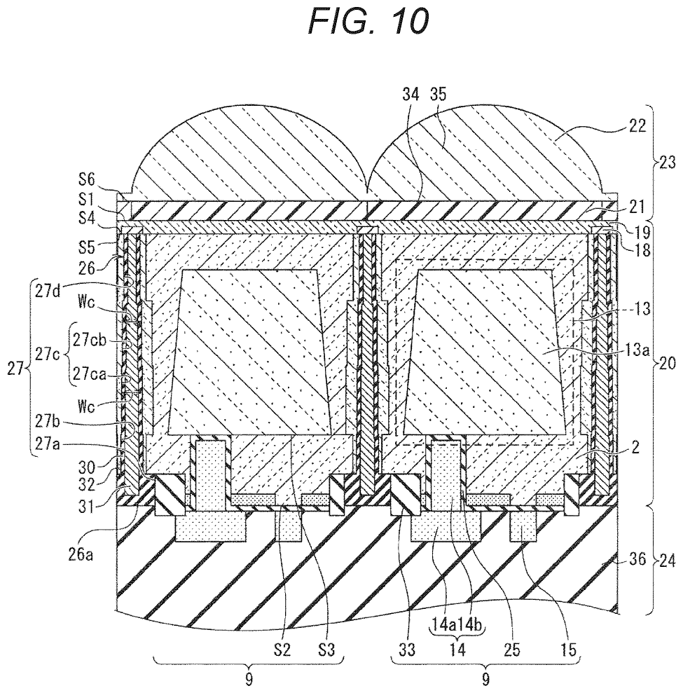

(1) Note that in the first embodiment, an example has been described, where a structure penetrating the substrate 2 from the front surface S2 side to the back surface S4 side is used as the structure of the trench portion 27, but other configurations can also be employed. For example, as illustrated in FIGS. 6 and 7, it is also possible to employ a structure that does not penetrate the substrate 2 and has a bottom portion in the substrate 2. FIG. 6 illustrates a case where the trench portion 27 has a structure in which the fourth trench portion 27d illustrated in FIG. 2 is omitted and only the first trench portion 27a, the second trench portion 27b, and the third trench portion 27c are provided, an opening is provided on the front surface S2 (surface opposite to the light receiving surface) of the substrate 2, and a bottom surface is provided inside the substrate 2. Furthermore, FIG. 7 illustrates a case where the trench portion 27 has a structure in which the first trench portion 27a and the second trench portion 27b illustrated in FIG. 2 are omitted and only the third trench portion 27c and the fourth trench portion 27d are provided, an opening is provided on the back surface S4 (light receiving surface) of the substrate 2, and a bottom surface is provided inside the substrate 2.
(2) Furthermore, in the first embodiment, an example has been described in which the trench portion 27 has a four-stage structure of the first trench portion 27a, the second trench portion 27b, the third trench portion 27c, and the fourth trench portion 27d, but other configurations can be employed. For example, as illustrated in FIGS. 8, 9, and 10, a three-stage structure or a structure of five or more stages can also be used. FIG. 8 illustrates a case where the trench portion 27 has a three-stage structure obtained by omitting the third trench portion 27c illustrated in FIG. 2 and extending the second trench portion 27b to the end portion of the fourth trench portion 27d on the wiring layer 24 side. Furthermore, FIG. 9 illustrates a case where the trench portion 27 has a three-stage structure obtained by omitting the third trench portion 27c illustrated in FIG. 2 and extending the fourth trench portion 27d to the end portion of the second trench portion 27b on the microlens array 22 side. Furthermore, FIG. 10 illustrates a case where the trench portion 27 has a five-stage structure obtained by dividing the third trench portion 27c into two stages (trench portions 27ca, 27cb).

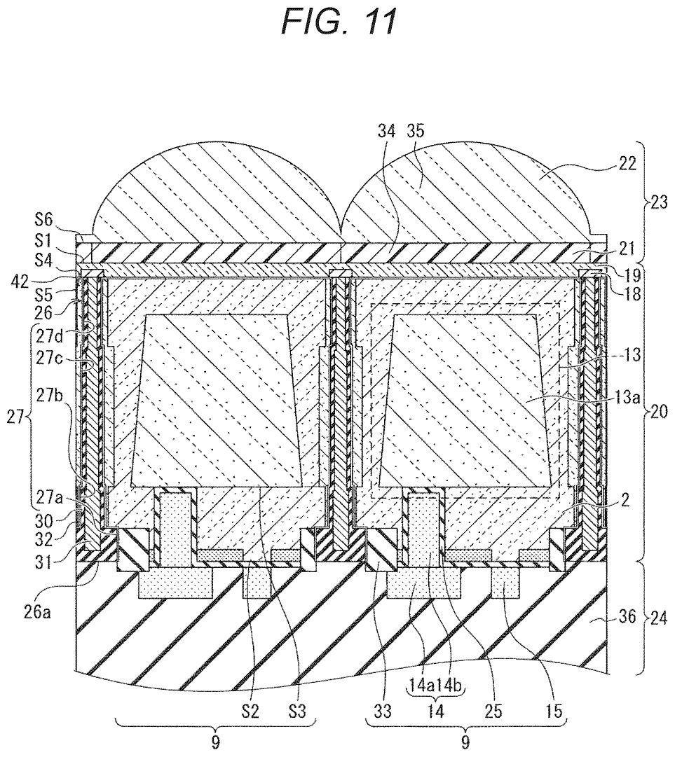

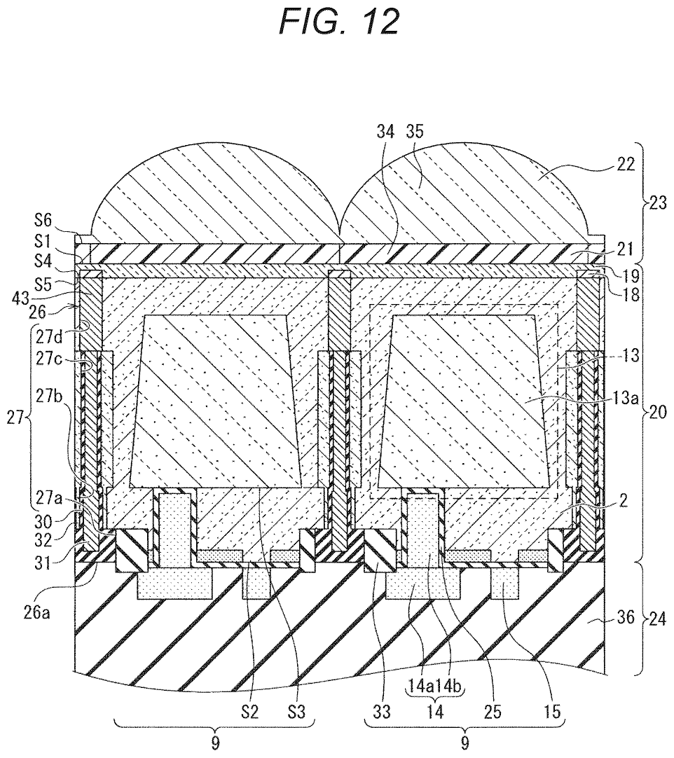

Furthermore, in FIG. 10, the magnitude relationship between the widths of the trench portions 27ca and 27cb is that the width Wca of the trench portion 27ca located on the second trench portion 27b side>the width Wcb of the trench portion 27cb located on the fourth trench portion 27d side. Furthermore, the magnitude relationship of the concentration of the impurity of the opposite conductivity type included in the portion (interface portion) located at the interface with the pixel separation portion 26 in the semiconductor region 32 of the opposite conductivity type (p-type) is: concentration Ccb in the region where the trench portion 27cb is located<concentration Cca in the region where the trench portion 27ca is located. Note that for example, Ccb>Cca can be adopted as the magnitude relationship of the concentration of the impurity of the opposite conductivity type included in the interface portion.
(3) Furthermore, although the first embodiment has described the example of using the structure where the inner side surfaces of the trench portion 27 are covered with the insulating film 30, other configurations can also be employed. For example, as illustrated in FIG. 11, a structure in which the entire back surface S4 side of the substrate 2 and the inner side surfaces of the trench portion 27 (the first trench portion 27a, the second trench portion 27b, the third trench portion 27c, and the fourth trench portion 27d) are continuously covered with a fixed charge film 42 may be used. FIG. 11 illustrates a case where the fixed charge film 42 is disposed between the inner side surface of the trench portion 27 and the insulating film 30. As a material of the fixed charge film 42, for example, a material that can generate fixed charges and enhance pinning by being deposited on the substrate 2 can be adopted. For example, a high refractive index material film or a high dielectric film having a negative charge can be adopted. Specific examples thereof include an oxide or nitride containing at least one element of hafnium (Hf), aluminum (Al), zirconium (Zr), tantalum (Ta), or titanium (Ti). As a result, at the interface between the photoelectric conversion unit 13 and the pixel separation portion 26, pinning can be enhanced (high hole concentration state), and generation of dark current can be suppressed.
(4) Furthermore, in the first embodiment, an example has been described in which the inner side surfaces of the trench portion 27 is covered with the insulating film 30 in the entire range inside the trench portion 27, and the embedded portion 31 is disposed inside the covered trench portion 27, but other configurations can be adopted. For example, as illustrated in FIG. 12, a structure may be used, where a conductor portion 43 in direct contact with the inner side surfaces of the trench portion 27 is disposed in a range from the back surface S4 of the substrate 2 to a predetermined depth in the trench portion 27. FIG. 12 illustrates a case where the fourth trench portion 27d, which is a portion located on the back surface S4 side of the trench portion 27 is filled with the conductor portion 43. As a method for forming the conductor portion 43, for example, a method can be employed in which the trench portion 27 is formed by the flow of FIGS. 5A to 5H, then the substrate 2 is dug along the fourth trench portion 27d from the back surface S4 side of the substrate 2, the embedded portion 31 in the fourth trench portion 27d is removed, and the removed portion is filled with the material of the conductor portion 43. FIG. 12 illustrates a case where the width of the fourth trench portion 27d is wider than the width of the fourth trench portion 27d illustrated in FIG. 2 due to digging of the substrate 2.

Accordingly, by applying a negative bias to the conductor portion 43, pinning can be enhanced, and deterioration of dark current characteristics and white spots can be suppressed. Examples of the method for applying a negative bias include a method of applying a negative bias through the light shielding film 18 on the back surface S4 of the substrate 2 or TSV. Furthermore, as a material of the conductor portion 43, for example, doped polysilicon (Poly-Si), amorphous silicon (a-Si), epitaxial growth silicon, a semiconductor other than silicon, or a metal can be adopted.
(5) Furthermore, in the first embodiment, a case where the charge accumulation region 13a is an n-type semiconductor region and the semiconductor region 32 of the opposite conductivity type is a p-type semiconductor region has been described as an example, but other configurations can be employed. For example, the charge accumulation region 13a may be a p-type semiconductor region and the semiconductor region 32 of the opposite conductivity type may be an n-type semiconductor region. The first embodiment and the modifications thereof can be applied to the solid-state imaging device 1 in which the charge accumulation region 13a is a p-type semiconductor region and the semiconductor region 32 of the opposite conductivity type is an n-type semiconductor region, and the description in the case of application is similar to the first embodiment or the modifications (1) to (4) thereof described above, so the detailed description thereof is herein omitted.
(6) Furthermore, the present technology is applicable to any photodetection device including not only the above-described solid-state imaging device 1 as an image sensor but also a ranging sensor also referred to as a time of flight (ToF) sensor that measures a distance, and the like. The ranging sensor is a sensor that emits irradiation light toward an object, detects reflected light that is the irradiation light reflected by a surface of the object, and calculates the distance to the object on the basis of a flight time since the emission of the irradiation light till the reception of the reflected light. As a light receiving pixel structure of the ranging sensor, the structure of the pixel 9 described above can be employed.

### 2. Second Embodiment: Application Example to Electronic Apparatus

The technology (present technology) according to the present disclosure may be applied to various electronic apparatuses.

FIG. 13 is a diagram illustrating an example of a schematic configuration of an imaging device (video camera, digital still camera or the like) as an electronic apparatus to which the present technology is applied.

As illustrated in FIG. 13, an imaging device 1000 includes a lens group 1001, a solid-state imaging device 1002 (the solid-state imaging device 1 according to the first embodiment), a digital signal processor (DSP) circuit 1003, a frame memory 1004, a monitor 1005, and a memory 1006. The DSP circuit 1003, the frame memory 1004, the monitor 1005, and the memory 1006 are connected to one another via a bus line 1007.

The lens group 1001 guides incident light (image light) from a subject to the solid-state imaging device 1002 to form an image on a light receiving surface (pixel region) of the solid-state imaging device 1002.

The solid-state imaging device 1002 includes the CMOS image sensor of the first embodiment described above. The solid-state imaging device 1002 converts an amount of incident light an image of which is formed on the light receiving surface by the lens group 1001 into an electric signal for each pixel and supplies the electric signal to the DSP circuit 1003 as a pixel signal.

The DSP circuit 1003 performs predetermined image processing on the pixel signal supplied from the solid-state imaging device 1002. Then, the DSP circuit 1003 supplies image signals for each frame, the image signals having been subjected to the image processing, to the frame memory 1004 to temporarily store the image signals in the frame memory 1004.

The monitor 1005 includes, for example, a panel type display device such as a liquid crystal panel or an organic electro luminescence (EL) panel. The monitor 1005 displays the image (moving image) of the subject on the basis of the pixel signals of each frame temporarily stored in the frame memory 1004.

The memory 1006 includes a DVD, a flash memory and the like. The memory 1006 reads and records the pixel signals of each frame temporarily stored in the frame memory 1004.

Note that the electronic apparatus to which the solid-state imaging device 1 can be applied is not limited to the imaging device 1000, and the solid-state imaging device 1 can also be applied to other electronic apparatuses.

Furthermore, the solid-state imaging device 1 according to the first embodiment is used as the solid-state imaging device 1002, but other configurations can also be employed. For example, other photodetection devices to which the present technology is applied, such as the solid-state imaging device 1 according to the modification of the first embodiment, may be used.

Note that, the present technology may also have the following configuration.
(1)

A photodetection device including:
a substrate;
a plurality of photoelectric conversion units which is arranged two-dimensionally in the substrate; and
a pixel separation portion which is arranged between the plurality of photoelectric conversion units adjacent to each other and has a trench portion,
in which in the substrate, a semiconductor region of an opposite conductivity type that is opposite to a conductivity type of a charge accumulation region of each of the plurality of photoelectric conversion units is formed in at least a part between each of the plurality of photoelectric conversion units and the pixel separation portion,
a width of the trench portion is different for each of a plurality of regions obtained by dividing the substrate along a thickness direction, and in a region where the semiconductor region of the opposite conductivity type is formed, the region being one of the plurality of regions, the width of the trench portion is greater in a first region than in a second region, the first region being a region on a side of a surface of the substrate opposite to a light receiving surface of the substrate, and the second region being a region on a side closer to the light receiving surface of the substrate than the first region is, and
a concentration of an impurity of the opposite conductivity type included in a part located at an interface with the pixel separation portion in the semiconductor region of the opposite conductivity type is lower in the first region than in the second region.
(2) The photodetection device according to (1),
in which the width of the trench portion is gradually narrowed from the side of the surface of the substrate opposite to the light receiving surface of the substrate toward the side of the light receiving surface.
(3)

The photodetection device according to (1) or (2),
in which a range in which the second region is located overlaps at least partially with a range in which the charge accumulation region is located in a depth direction from the surface of the substrate opposite to the light receiving surface of the substrate.
(4)

The photodetection device according to any one of (1) to (3),
in which the second region includes a third region that is a region located on a side of the first region and a fourth region that is a region located on a side far from the first region, and
a concentration of an impurity of the opposite conductivity type included in a part located at an interface with the pixel separation portion in the semiconductor region of the opposite conductivity type is lower in the fourth region than in the third region.
(5)

The photodetection device according to any one of (1) to (4) further including:
a plurality of pixel transistors which is formed on the surface of the substrate opposite to the light receiving surface of the substrate,
in which an end of the pixel separation portion opposite to a light receiving surface of the pixel separation portion reaches the surface of the substrate opposite to the light receiving surface of the substrate, and
the substrate includes an element separation portion that is formed from the surface of the substrate opposite to the light receiving surface of the substrate to a predetermined depth, and in contact with a surface of the pixel separation portion on a side of a corresponding one of the plurality of photoelectric conversion units.
(6)

The photodetection device according to (5),
in which the plurality of pixel transistors includes a transfer transistor which includes a vertical gate electrode that has a columnar shape and extends from the surface of the substrate opposite to the light receiving surface of the substrate toward a corresponding one of the plurality of photoelectric conversion units, and
a range in which the element separation portion is located overlaps at least partially with a range in which the vertical gate electrode is located in a depth direction from the surface of the substrate opposite to the light receiving surface of the substrate.
(7)

The photodetection device according to any one of (1) to (6),
in which the pixel separation portion further includes a fixed charge film that covers an inner side surface of the trench portion.
(8)

The photodetection device according to any one of (1) to (7),
in which an end of the pixel separation portion on a side of a light receiving surface of the pixel separation portion reaches the light receiving surface of the substrate, and
the pixel separation portion further includes a conductor portion that is disposed in a range from the light receiving surface of the substrate to a predetermined depth inside the trench portion and in direct contact with an inner side surface of the trench portion.
(9)

An electronic apparatus including:
a photodetection device including a substrate, a plurality of photoelectric conversion units which is arranged two-dimensionally on the substrate, and a pixel separation portion which is arranged between the plurality of photoelectric conversion units adjacent to each other and has a trench portion, in which in the substrate, a semiconductor region of an opposite conductivity type that is opposite to a conductivity type of a charge accumulation region of each of the plurality of photoelectric conversion units is formed in at least a part between each of the plurality of photoelectric conversion units and the pixel separation portion, a width of the trench portion is different for each of a plurality of regions obtained by dividing the substrate along a thickness direction, and in a region where the semiconductor region of the opposite conductivity type is formed, the region being one of the plurality of regions, the width of the trench portion is greater in a first region than in a second region, the first region being a region on a side of a surface of the substrate opposite to a light receiving surface of the substrate, and the second region being a region on a side closer to the light receiving surface of the substrate than the first region is, and a concentration of an impurity of the opposite conductivity type included in a part located at an interface with the pixel separation portion in the semiconductor region of the opposite conductivity type is lower in the first region than in the second region.

### REFERENCE SIGNS LIST

1 Solid-state imaging device
2 Substrate
3 Pixel region
4 Vertical drive circuit
5 Column signal processing circuit
6 Horizontal drive circuit
7 Output circuit
8 Control circuit
9 Pixel
10 Pixel drive wiring
11 Vertical signal line
12 Horizontal signal line
13 Photoelectric conversion unit
13a Charge accumulation region
14 Transfer transistor
14a Planar gate electrode
14b Vertical gate electrode
15 Reset transistor
16 Amplification transistor
17 Selection transistor
18 Light shielding film
19 Planarization film
20 Light receiving layer
21 Color filter array
22 Microlens array
23 Light condensing layer
24 Wiring layer
25 Gate insulating film
26 Pixel separation portion
27 Trench portion
27a First trench portion
27b Second trench portion
27c Third trench portion
27d Fourth trench portion
28 First region
29 Second region
29c Third region
29d Fourth region
30, 30a, 30b Insulating film
31 Embedded portion
32, 32b, 32c Semiconductor region
33 Element separation portion
34 Color filter
35 Microlens
36 Interlayer insulating film
37 Incident light
38 Hard mask
39, 40, 41 Oxide film
42 Fixed charge film
43 Conductor portion
50 Front surface-side region
51 Back surface-side region

1. A photodetection device comprising:
a substrate;
a plurality of photoelectric conversion units which is arranged two-dimensionally in the substrate; and
a pixel separation portion which is arranged between the plurality of photoelectric conversion units adjacent to each other and has a trench portion,
wherein in the substrate, a semiconductor region of an opposite conductivity type that is opposite to a conductivity type of a charge accumulation region of each of the plurality of photoelectric conversion units is formed in at least a part between each of the plurality of photoelectric conversion units and the pixel separation portion,
a width of the trench portion is different for each of a plurality of regions obtained by dividing the substrate along a thickness direction, and in a region where the semiconductor region of the opposite conductivity type is formed, the region being one of the plurality of regions, the width of the trench portion is greater in a first region than in a second region, the first region being a region on a side of a surface of the substrate opposite to a light receiving surface of the substrate, and the second region being a region on a side closer to the light receiving surface of the substrate than the first region is, and
a concentration of an impurity of the opposite conductivity type included in a part located at an interface with the pixel separation portion in the semiconductor region of the opposite conductivity type is lower in the first region than in the second region.

2. The photodetection device according to claim 1,
wherein the width of the trench portion is gradually narrowed from the side of the surface of the substrate opposite to the light receiving surface of the substrate toward the side of the light receiving surface.

3. The photodetection device according to claim 1,
wherein a range in which the second region is located overlaps at least partially with a range in which the charge accumulation region is located in a depth direction from the surface of the substrate opposite to the light receiving surface of the substrate.

4. The photodetection device according to claim 1,
wherein the second region includes a third region that is a region located on a side of the first region and a fourth region that is a region located on a side far from the first region, and
a concentration of an impurity of the opposite conductivity type included in a part located at an interface with the pixel separation portion in the semiconductor region of the opposite conductivity type is lower in the fourth region than in the third region.

5. The photodetection device according to claim 1 further comprising:
a plurality of pixel transistors which is formed on the surface of the substrate opposite to the light receiving surface of the substrate,
wherein an end of the pixel separation portion opposite to a light receiving surface of the pixel separation portion reaches the surface of the substrate opposite to the light receiving surface of the substrate, and
the substrate includes an element separation portion that is formed from the surface of the substrate opposite to the light receiving surface of the substrate to a predetermined depth, and in contact with a surface of the pixel separation portion on a side of a corresponding one of the plurality of photoelectric conversion units.

6. The photodetection device according to claim 5,
wherein the plurality of pixel transistors includes a transfer transistor which includes a vertical gate electrode that has a columnar shape and extends from the surface of the substrate opposite to the light receiving surface of the substrate toward a corresponding one of the plurality of photoelectric conversion units, and
a range in which the element separation portion is located overlaps at least partially with a range in which the vertical gate electrode is located in a depth direction from the surface of the substrate opposite to the light receiving surface of the substrate.

7. The photodetection device according to claim 1,
wherein the pixel separation portion further includes a fixed charge film that covers an inner side surface of the trench portion.

8. The photodetection device according to claim 1,
wherein an end of the pixel separation portion on a side of a light receiving surface of the pixel separation portion reaches the light receiving surface of the substrate, and
the pixel separation portion further includes a conductor portion that is disposed in a range from the light receiving surface of the substrate to a predetermined depth inside the trench portion and in direct contact with an inner side surface of the trench portion.

9. An electronic apparatus comprising:
a photodetection device including a substrate, a plurality of photoelectric conversion units which is arranged two-dimensionally in the substrate, and a pixel separation portion which is arranged between the plurality of photoelectric conversion units adjacent to each other and has a trench portion, wherein in the substrate, a semiconductor region of an opposite conductivity type that is opposite to a conductivity type of a charge accumulation region of each of the plurality of photoelectric conversion units is formed in at least a part between each of the plurality of photoelectric conversion units and the pixel separation portion, a width of the trench portion is different for each of a plurality of regions obtained by dividing the substrate along a thickness direction, and in a region where the semiconductor region of the opposite conductivity type is formed, the region being one of the plurality of regions, the width of the trench portion is greater in a first region than in a second region, the first region being a region on a side of a surface of the substrate opposite to a light receiving surface of the substrate, and the second region being a region on a side closer to the light receiving surface of the substrate than the first region is, and a concentration of an impurity of the opposite conductivity type included in a part located at an interface with the pixel separation portion in the semiconductor region of the opposite conductivity type is lower in the first region than in the second region.
